(19) United States
(12) Patent Application Publication
(10) Pub. No.: US 2025/0141082 A1
(43) Pub. Date: May 1, 2025

(54) MODULATION UNIT AND PREPARATION METHOD THEREOF, MODULATION DEVICE AND DRIVING METHOD THEREOF

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Feng Wang, Beijing (CN); Long Wang, Beijing (CN); Yanzhao Li, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/687,870

(22) PCT Filed: Dec. 6, 2022
(86) PCT No.: PCT/CN2022/136918

§ 371 Date: Feb. 29, 2024

(51) Int. Cl. H01P 7/06; H01P 7/08; H03F 3/387

(52) U.S. Cl. CPC H01P 7/06; H01P 7/08; H03F 3/387

(57) ABSTRACT

A modulation unit includes a base plate, including a substrate, and a metal layer provided on one side of the substrate, the metal layer is provided with a slit; and a driving layer, provided on one side of the base plate, including a polar plate and a driving structure, with a gap between the polar plate and the base plate; wherein the modulation unit includes at least one resonant structure including a slit, a polar plate, and a driving structure; in the same resonant structure, the driving structure is connected to the polar plate for driving the polar plate to move in response to a driving signal, to change a size of an overlap region of an orthographic projection of the polar plate on the base plate and the slit, to adjust a resonant frequency of the resonant structure.

### FIELD

The present disclosure relates to the technical field of microwave and wireless communications and more particularly, to a modulation unit and a preparation method thereof, a modulation device and a driving method thereof.

### BACKGROUND

Since 2014, digital meta surfaces and reconfigurable meta surfaces have attracted more and more attention from researchers in the field of wireless communications. Especially in recent years, intelligent meta surface technology with market application value has been developed.

### SUMMARY

The present disclosure provides a modulation unit, including:
a base plate, including a substrate, and a metal layer provided on one side of the substrate, wherein the metal layer is provided with a slit; and
a driving layer, provided on one side of the base plate, wherein the driving layer includes a polar plate and a driving structure, and a gap is provided between the polar plate and the base plate;
wherein the modulation unit includes at least one resonant structure including the slit, the polar plate, and the driving structure; and
in the same resonant structure, the driving structure is connected to the polar plate for driving the polar plate to move in response to a driving signal, to change a size of an overlap region of an orthographic projection of the polar plate on the base plate and the slit, to adjust a resonant frequency of the resonant structure.

In some implementations, in the same resonant structure, a moving direction of the polar plate and an extension direction of the slit are perpendicular to each other.

In some implementations, the slit includes a strip-like slit, the extension direction of the slit is an extension direction of the strip-like slit.

In some implementations, the slit further includes at least one branch slit, and the at least one branch slit and the strip-like slit are communicated and intersected with each other.

In some implementations, the at least one branch slit is located on a same side of the strip-like slit; and in the same resonant structure, orthographic projections of the driving structure and at least part of the polar plate on the base plate is located on a side of the strip-like slit away from the branch slit.

In some implementations, the at least one resonant structure includes a first resonant structure and a second resonant structure, an extension direction of the slit located in the first resonant structure is a first direction, an extension direction of the slit located in the second resonant structure is a second direction, and the first direction and the second direction are perpendicular to each other.

In some implementations, the at least one resonant structure further includes a third resonant structure and a fourth resonant structure, operating frequency bands of the first resonant structure and the second resonant structure are a first frequency band, operating frequency bands of the third resonant structure and the fourth resonant structure are a second frequency band, and the first frequency band is different from the second frequency band.

In some implementations, the extension direction of the slit located in the third resonant structure is the second direction, and the extension direction of the slit located in the fourth resonant structure is the first direction; and
in the first direction, an orthographic projection of the first resonant structure on the base plate and an orthographic projection of the fourth resonant structure on the base plate are at least partially overlapped;
in the second direction, an orthographic projection of the second resonant structure on the base plate and an orthographic projection of the third resonant structure on the base plate are at least partially overlapped.

In some implementations, a distance between the polar plate and the base plate is less than or equal to a width of the slit, and the width of the slit is a dimension of the slit in a direction perpendicular to an extension direction of the slit.

In some implementations, a length of the slit in an extension direction of the slit is less than or equal to λ₁/2n₁,λ₁ is an operating wavelength of a resonant structure to which the slit belongs, and n₁ is an equivalent refractive index of a material filling the slit and surrounding the slit.

In some implementations, in the same resonant structure, the orthographic projection of the polar plate on the base plate is centrally located in the slit along an extension direction of the slit.

In some implementations, in the same resonant structure, a ratio between a length of the polar plate and a length of the slit is greater than or equal to ⅓ and less than or equal to 4/3 along an extension direction of the slit.

In some implementations, the driving structure includes a MEMS switch, the MEMS switch includes a stator comb-like electrode and a mover comb-like electrode which are oppositely provided in a moving direction of the polar plate;
wherein a comb ridge of the stator comb-like electrode is fixed on the base plate, comb teeth of the stator comb-like electrode face the mover comb-like electrode, comb teeth of the mover comb-like electrode face the stator comb-like electrode, two ends of a comb ridge of the mover comb-like electrode are fixed on the base plate, and one side surface of the comb ridge of the mover comb-like electrode away from the comb teeth of the mover comb-like electrode is connected to the polar plate via a cantilever beam; and
the stator comb-like electrode and the mover comb-like electrode are used for generating an electrostatic force under action of the driving signal, and the mover comb-like electrode drives the polar plate to move under action of the electrostatic force.

In some implementations, the comb ridge of the mover comb-like electrode is reused as the polar plate.

In some implementations, the polar plate, the mover comb-like electrode, the stator comb-like electrode, and the cantilever beam are provided in a same layer and of a same material.

In some implementations, the driving layer includes at least one of a conductive layer and a highly doped crystallized silicon layer provided on a side of the conductive layer close to the base plate.

The present disclosure provides a modulation device, including a modulation panel, wherein the modulation panel includes the at least one modulation unit described as any implementation.

In some implementations, the modulation device includes a plurality of the modulation panels arranged in stacked and spaced apart from each other.

In some implementations, a spacing between two adjacent modulation panels is greater than or equal to λ₂/2n₂, λ₂ is an operating wavelength of the modulation device, and n₂ is a refractive index of a material filled between the two adjacent modulation panels.

The present disclosure provides a driving method, applied to the modulation device described as any implementation, wherein the driving method includes:
providing the driving signal to the driving structure, so that the driving structure drives the polar plate to move in response to the driving signal, to change the size of the overlap region of the orthographic projection of the polar plate on the base plate and the slit, to adjust the resonant frequency of the resonant structure.

In some implementations, when the at least one resonant structure includes a first resonant structure and a second resonant structure, and an extension direction of the slit located in the first resonant structure and an extension direction of the slit located in the second resonant structure are perpendicular to each other, the step of providing the driving signal to the driving structure includes:
providing a first driving signal to a first driving structure, and providing a second driving signal to a second driving structure, so that a phase change generated by an electromagnetic wave passing through the first resonant structure is different from a phase change generated by the electromagnetic wave passing through the second resonant structure, to change a polarization state of the electromagnetic wave; wherein the first driving structure is a driving structure located in the first resonant structure and the second driving structure is a driving structure located in the second resonant structure.

In some implementations, when the modulation device includes a first modulation panel and a second modulation panel arranged in stacked and spaced apart from each other, the step of providing a first driving signal to a first driving structure and providing a second driving signal to a second driving structure includes:
providing the first driving signal to the first driving structures located in the first modulation panel and the second modulation panel, respectively, providing the second driving signal to the second driving structures located in the first modulation panel and the second modulation panel, respectively, so that an electromagnetic wave passing through the first modulation panel is converted from a first polarization state to a second polarization state, and an electromagnetic wave passing through the second modulation panel is converted from the second polarization state to a third polarization state.

In some implementations, the first polarization state and the third polarization state are linear polarizations with different electric vector vibration directions, and the second polarization state is elliptical polarization or circular polarization; or
the first polarization state and the third polarization state are elliptical polarization or circular polarization with different electric vector rotation directions, and the second polarization state is the linear polarization.

The present disclosure provides a preparation method of a modulation unit, including:
providing a base plate, wherein the base plate includes a substrate and a metal layer provided on one side of the substrate, and the metal layer is provided with a slit;
forming a driving layer on one side of the base plate to obtain the modulation unit; wherein the driving layer includes a polar plate and a driving structure, with a gap between the polar plate and the base plate, and the modulation unit includes at least one resonant structure, and the resonant structure includes the slit, the polar plate and the driving structure, within the same resonant structure, the driving structure is connected to the polar plate for driving the polar plate to move in response to a driving signal, to change a size of an overlap region of an orthographic projection of the polar plate on the base plate and the slit, to adjust a resonant frequency of the resonant structure.

In some implementations, the driving structure includes a MEMS switch, and the MEMS switch includes a stator comb-like electrode and a mover comb-like electrode which are oppositely provided in the moving direction of the polar plate, comb teeth of the stator comb-like electrode face the mover comb-like electrode, comb teeth of the mover comb-like electrode face the stator comb-like electrode, a side surface of a comb ridge of the mover comb-like electrode away from the comb teeth is connected to the polar plate via a cantilever beam, and the step of providing a base plate includes:
providing a substrate;
forming a metal layer on one side of the substrate, wherein the metal layer is provided with a slit thereon;
forming a planar layer and a passivation layer successively on the side of the metal layer away from the substrate to obtain the base plate;
the step of forming a driving layer on one side of the base plate includes:
forming a sacrificial layer on a side of the passivation layer away from the substrate;
using a patterning process to form the driving layer on the side of the sacrificial layer away from the substrate, wherein the driving layer includes the polar plate, the mover comb-like electrode, the stator comb-like electrode, and the cantilever beam;
etching the sacrificial layer to form a support structure and the gap, the support structure including a first support pattern and a second support pattern, wherein the first support pattern is located between the comb ridge of the stator comb-like electrode and the base plate for fixing the comb ridge of the stator comb-like electrode on the base plate; the second support pattern is located between the two ends of the comb ridge of the mover comb-like electrode and the base plate for fixing the two ends of the comb ridge of the mover comb-like electrode on the base plate; the gap is located at least between the polar plate and the base plate, between the cantilever beam and the base plate, between the middle region of the comb ridge of the mover comb-like electrode and the base plate, and between the comb teeth of the mover comb-like electrode and the base plate.

The above description is only an overview of the disclosed technical solution. In order to have a clearer understanding of the disclosed technical means, it can be implemented according to the content of the specification. In order to make the above and other purposes, features, and advantages of the present disclosure more obvious and easier to understand, the specific implementation methods of the present disclosure are listed below.

### BRIEF DESCRIPTION OF THE DRAWINGS

In order to provide a clearer explanation of the technical solutions in the embodiments of the present disclosure or related art, a brief introduction will be given below to the accompanying drawings required in the embodiments or related technical descriptions. It is obvious that the accompanying drawings in the following description are some embodiments of the present disclosure. For those skilled in the art, other accompanying drawings can be obtained based on these drawings without creative labor. It should be noted that the proportions in the attached figures are only for illustrative purposes and do not represent the actual proportions.

FIG. 1 schematically shows a cross-sectional structure diagram of a modulation unit;

FIG. 2 schematically shows a plan structure diagram of a first kind of modulation unit;

FIG. 3 schematically shows a plan structure diagram of a modulation unit corresponding to two kinds of slits;

FIG. 4 schematically shows simulation results of a first kind of resonant structure;

FIG. 5 schematically shows simulation results of a second kind of resonant structure;

FIG. 6 schematically shows a process of converting a linearly polarized electromagnetic wave into a nearly circularly polarized electromagnetic wave;

FIG. 7 schematically shows a plan structure diagram of a second kind of modulation unit;

FIG. 8 schematically shows a plan structure diagram of a third kind of modulation unit;

FIG. 9 schematically shows simulation results of a resonant structure in a third kind of modulation unit;

FIG. 10 schematically shows a plan structure diagram of a modulation panel;

FIG. 11 schematically shows a cross-sectional structure diagram of a modulation device;

FIG. 12 schematically shows two linearly polarized electromagnetic waves having different vibration directions of electric vector;

FIG. 13 schematically shows a preparation flow diagram of a modulation unit.

### DETAILED DESCRIPTION

In order to clarify the purpose, technical solution, and advantages of the embodiments of the present disclosure, the following will provide a clear and complete description of the technical solution in the embodiments of the present disclosure in conjunction with the accompanying drawings. Obviously, the embodiments of the present disclosure are a part of the embodiments of the present disclosure, not all of them. Based on the embodiments of the present disclosure, all other embodiments obtained by persons skilled in the art without creative labor fall within the scope of protection of the present disclosure.

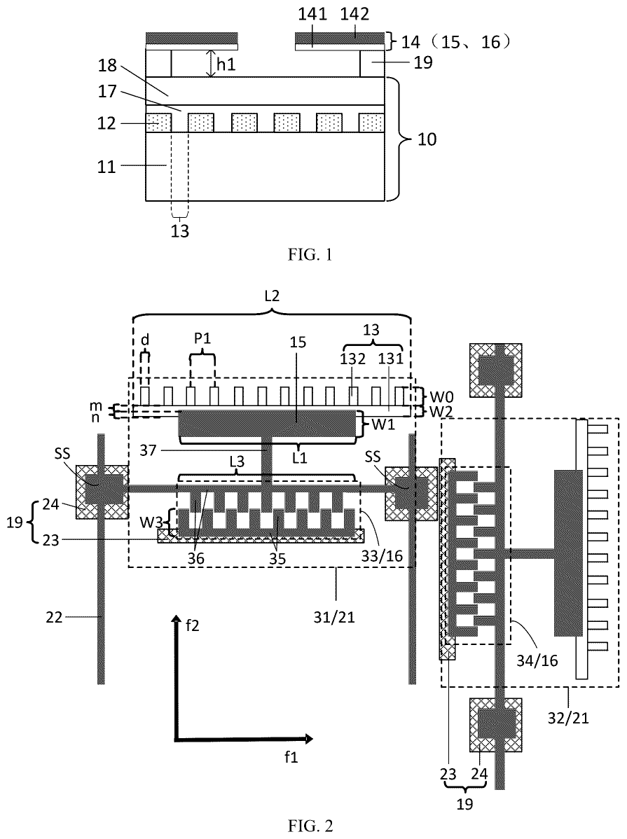

The present disclosure provides a modulation unit, and a cross-sectional structure diagram of the modulation unit is schematically shown referring to FIG. 1. As shown in FIG. 1, the modulation unit includes: a base plate 10 including: a substrate 11 and a metal layer 12 provided on one side of the substrate 11, the metal layer 12 is provided with a slit 13; and a driving layer 14, provided on one side of the base plate 10, including a polar plate 15 and a driving structure 16, with a gap h1 between the polar plate 15 and the base plate 10.

A plan structure diagram of the modulation unit is schematically shown referring to FIG. 2. As shown in FIG. 2, the modulation unit includes at least one resonant structure 21. The resonant structure 21 includes the slit 13, the polar plate 15, and the driving structure 16. In the same resonant structure 21, the driving structure 16 is connected to the polar plate 15 for driving the polar plate 15 to move in response to a driving signal, to change a size of an overlap region of an orthographic projection of the polar plate 15 on the base plate 10 and the slit 13, to adjust a resonant frequency of the resonant structure 21.

As shown in FIG. 1, the polar plate 15 is suspended on the base plate 10 with a gap h1 therebetween.

By arranging the driving structure 16 to drive the polar plate 15 to translate, the projection position of the polar plate 15 in the slit 13 is changed, and the resonant frequency of the resonant structure 21 composed of the slit 13 and the polar plate 15 is further changed. Therefore, the modulation unit provided by the present disclosure can achieve tuning of frequency, phase, and polarization of the electromagnetic wave.

The inventors have found that if only the driving structure 16 and the polar plate 15 are provided in the resonant structure 21, the capacitance effect generated by the driving structure 16 moving the polar plate 15 is small, and tuning of the frequency, phase, and polarization of the electromagnetic wave is not easily achieved.

By providing slits 13 in the resonant structure 21, the sensitivity of the resonant frequency of the resonant structure 21 to the movement of the polar plate 15 can be improved, and the modulation unit provided by the present disclosure can sensitively tune the frequency, phase, and polarization of the electromagnetic wave transmitted through the resonant structure 21 even if the polar plate 15 of a smaller size is used or the moving range of the polar plate 15 is small.

Illustratively, as shown in FIG. 1, the base plate 10 further includes a planar layer 17 and a passivation layer 18 located on the side of the metal layer 12 away from the substrate 11, the planar layer 17 is provided close to the metal layer 12 and the driving layer 14 is provided on the side of the passivation layer 18 away from the substrate 11. A support structure 19 may be provided between the base plate 10 and the driving layer 14. Specifically, the support structure 19 may be disposed between the driving structure 16 and the base plate 10 for fixing the driving structure 16 to the base plate 10.

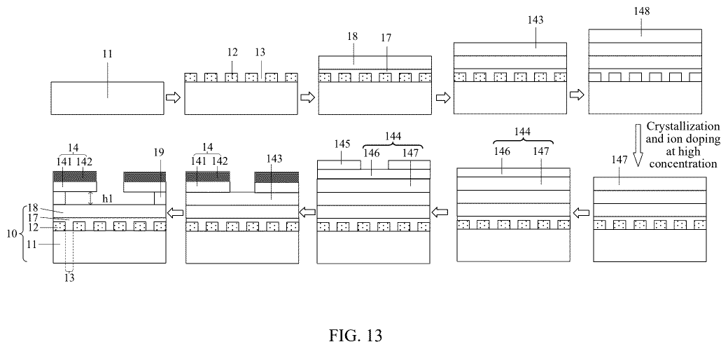

In practice, a sacrificial layer 143 may first be formed on the base plate 10 (referring to FIG. 13), the driving layer 14 (including the polar plate 15 and the driving structure 16) may then be patterned on the side of the sacrificial layer 143 away from the base plate 10, and the sacrificial layer 143 may then be etched so that a gap h1 may be formed between the polar plate 15 and the base plate 10, while a support structure 19 is formed between the driving structure 16 and the base plate 10.

The driving layer 14 may include a conductive layer 142, and may further include a highly doped crystallized silicon layer 141 provided on the side of the conductive layer 142 close to the base plate 10. Here, the conductive layer 142 may use one or more of conductive materials such as copper, silver, aluminum, neodymium, and molybdenum. By providing a highly doped crystallized silicon layer 141, the stability and reliability of the driving structure 16 can be improved.

In some embodiments, in the same resonant structure 21, the moving direction of the polar plate 15 and the extension direction of the slit 13 are perpendicular to each other.

As shown in FIG. 2, in the first resonant structure 31, the extension direction of the slit 13 is a first direction f1, and the moving direction of the polar plate 15 is a second direction f2; in the second resonant structure 32, the extension direction of the slit 13 is the second direction f2, and the moving direction of the polar plate 15 is the first direction f1. Wherein the second direction f2 is perpendicular to the first direction f1.

By arranging that the moving direction of the polar plate 15 is perpendicular to the extension direction of the slit 13, i.e., the polar plate 15 is moved in the direction of the narrow side of the slit 13, the sensitivity of the resonant frequency of the resonant structure 21 to the movement of the polar plate 15 can be further increased.

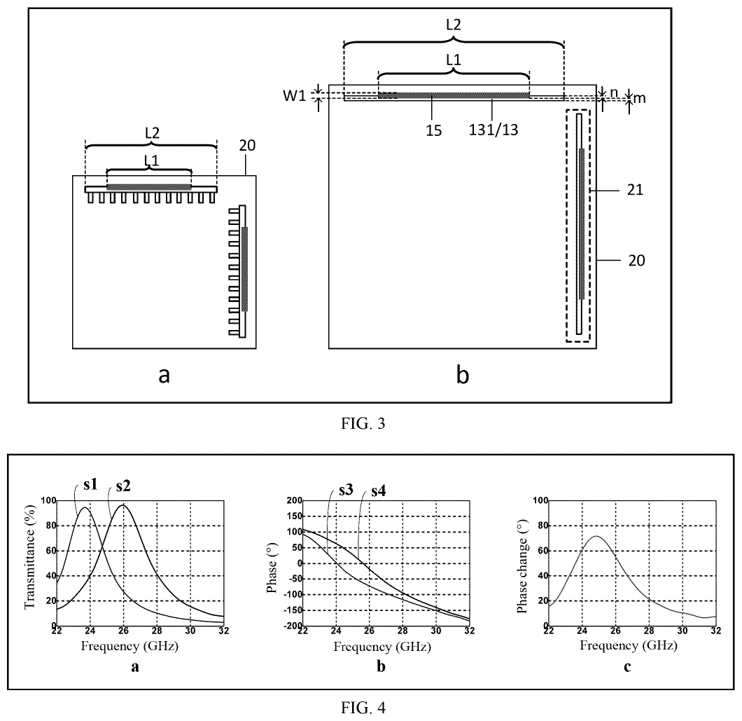

In some embodiments, as shown in FIG. 2 or b of FIG. 3, the slit 13 includes a strip-like slit 131, and the extension direction of the slit 13 is the extension direction of the strip-like slit 131.

Illustratively, as shown in b of FIG. 3, the slit 13 is a strip-like slit 131.

In some embodiments, as shown in FIG. 2, the slit 13 may further include: at least one branch slit 132 communicating and intersecting with the strip-like slit 131.

Illustratively, as shown in FIG. 2, the branch slits 132 are perpendicular to the strip-like slits 131. The plurality of branch slits 132 are located on the same side of the strip-like slit 131 and are parallel to each other. In FIG. 2, the slits 13 are comb-like slits, the strip-like slits 131 are comb ridges, and the branch slits 132 are comb teeth.

By providing the branch slit 132, the length L2 of the strip-like slit 131 (namely, the dimension of the strip-like slit 131 in the extension direction thereof) can be shortened, thereby reducing the dimensions of the polar plate 15 and the modulation unit 20, facilitating the miniaturization of the modulation unit and improving the practicality and reliability of the modulation unit, and at the same time, reducing the dimension of the polar plate 15 helps to reduce the driving voltage of the driving structure 16.

In some embodiments, as shown in FIG. 2, at least one branch slit 132 is located on the same side of the strip-like slit 131, and in the same resonant structure 21, the orthographic projection of the driving structure 16 and at least part of the polar plate 15 on the base plate 10 is located on the side of the strip-like slit 131 away from the branch slit 132.

As shown in FIG. 2, in the first resonant structure 31, the extension direction of the strip-like slit 131 is a first direction f1, the branch slit 132 is located on the upper side of the strip-like slit 131, and the orthographic projection of the driving structure 16 and at least part of the polar plate 15 on the base plate 10 is located on the lower side of the strip-like slit 131; in the second resonant structure 32, the extension direction of strip-like slit 131 is the second direction f2, the branch slit 132 is located on the right side of the strip-like slit 131, and the orthographic projection of the driving structure 16 and at least part of the polar plate 15 on the base plate 10 is located on the left side of the strip-like slit 131.

By arranging the orthographic projection of the driving structure 16 and at least part of the polar plate 15 on the base plate 10 and the branch slit 132 located on the two sides of the strip-like slit 131 respectively, on the one hand, shielding of the branch slit 132 by the driving structure 16 and the polar plate 15 can be avoided and the transmittance of the electromagnetic wave can be affected, and on the other hand, the overlap region of the orthographic projection of the polar plate 15 on the base plate 10 and the slit 13 can always be located in the strip-like slit 131, so as to further improve the sensitivity of the resonant frequency of the resonant structure 21 to the movement of the polar plate 15.

As shown in FIG. 2, the length of the branch slit 132 (namely, the dimension of the comb teeth of the comb-like slit in FIG. 2 in the direction perpendicular to the extension direction of the strip-like slit 131) is W0, the width of the branch slit 132 (namely, the dimension of the comb teeth of the comb-like slit in FIG. 2 in the extension direction of the strip-like slit 131) is d, and the arrangement period of the branch slit 132 is P1.

As shown in FIG. 2 and b of FIG. 3, the width of the strip-like slit 131 (i.e., the dimension of the strip-like slit 131 in the direction perpendicular to the extension direction thereof) is m+n, m is the dimension of the strip-like slit 131 in the direction perpendicular to the extension direction thereof which is not covered by the polar plate 15, and n is the dimension of the strip-like slit 131 in the direction perpendicular to the extension direction thereof which is covered by the polar plate 15. The length of the polar plate 15 (the dimension of the polar plate 15 in the extension direction of the strip-like slit 131) is L1, and the width of the polar plate 15 (the dimension of the polar plate 15 in the direction perpendicular to the extension direction of the strip-like slit 131) is W1. In a resonant structure 21, the orthographic projection position of the polar plate 15 in the slit 13 has a large influence on the resonant frequency of the resonant structure 21 or the frequency that can be transmitted by the resonant structure 21, we use here m:n represents the projection position of the polar plate 15 in the slit 13.

In FIG. 2, m+n=60 μm, d=60 μm, P1=210 μm, W0=500 μm, L1=1500 μm, W1=100 μm, and the slit 13 includes a 14 periodic comb teeth structure. In b of FIG. 3, m+n=60 μm, and the length L2 of the slit 13 is 4.4 mm.

Referring to a of FIG. 4, the transmittance-frequency curve of the resonant structure 21 (as shown in FIG. 2) using comb-like slits is shown. When m:n=30:30, the transmittance of normal incident millimeter wave is shown as s1 curve in FIG. 4. When the polar plate 15 moves by 20 μm driven by the driving structure 16 so that m:n=10:50, the transmittance of normal incident millimeter wave is shown as s2 curve in FIG. 4. It can be seen that by arranging the driving structure 16 to drive the polar plate 15 to translate, the frequency of the electromagnetic wave can be tuned, and the resonant structure 21 shown in FIG. 2 can achieve a high transmittance in the millimeter wave band, and the insertion loss of the modulation unit is less than 2 dB.

As the transmission frequency (the frequency of the electromagnetic wave transmitted through the resonant structure 21) changes, the transmission phase (the phase of the electromagnetic wave transmitted through the resonant structure 21) also changes accordingly. The phase-frequency curve of the resonant structure 21 employing comb-like slits is shown referring to b in FIG. 4. When m:n=30:30, the transmission phase of the normal incident millimeter wave is shown as the s3 curve in FIG. 4, when m:n=10:50, the transmission phase of the normal incident millimeter wave is shown as the s4 curve in FIG. 4. It can be seen that the resonant structure 21 shown in FIG. 2 is phase-tuned for electromagnetic waves as the transmission phase changes significantly after a 20 μm displacement of the projection position of the polar plate 15 on the slit 13.

Referring to a of FIG. 5, the transmittance-frequency curve of the resonant structure 21 (as shown in b of FIG. 3) employing the strip-like slits is shown. When m:n=30:30, the transmittance of normal incident millimeter wave is shown as the s5 curve in FIG. 5. When the polar plate 15 is driven by the driving structure 16 to move 20 μm so that when m:n=10:50, the transmittance of normal incident millimeter wave is shown as the s6 curve in FIG. 5. It can be seen that by arranging the driving structure 16 to drive the polar plate 15 to translate, the frequency of the electromagnetic wave can be tuned; the resonant structure 21 shown in b of FIG. 3 can achieve a high transmittance in the millimeter wave band, and the insertion loss of the modulation unit is less than 2 dB.

Referring to b in FIG. 5, the phase-frequency curve of the resonant structure 21 employing strip-like slits is shown. When m:n=30:30, the transmission phase of the normal incident millimeter wave is shown as the s7 curve in FIG. 5, when m:n=10:50, the transmission phase of the normal incident millimeter wave is shown as the s8 curve in FIG. 5. It can be seen that when the projection position of the polar plate 15 on the slit 13 is shifted by 20 μm, the phase of the transmission changes significantly to achieve phase tuning of the electromagnetic wave.

Comparing the simulation results of the two resonant structures 21 shown in FIG. 4 and FIG. 5, it can be seen that the transmission frequency and the transmission phase of the electromagnetic wave can be adjusted by the resonant structure using both the strip-like slits 131 and the comb-like slits.

Referring to FIG. 3, two modulation units 20 using comb-like slits and strip-like slits, respectively, are shown. In order to make both modulation units 20 have a transmission frequency of about 26 GHz, the length of the strip-like slit 131 (L2 in b of FIG. 3) is about three times the length of the comb-like slit (L2 in a of FIG. 3). The area of the modulation unit 20 using the strip-like slits 131 is about three times as large as the area of the modulation unit 20 using the comb-like slits, and the length of the polar plate 15 corresponding to the strip-like slits 131 (L1 in b of FIG. 3) is about twice as large as the length of the polar plate 15 corresponding to the comb-like slits (L1 in a of FIG. 3).

The difference between phase at m:n=30:30 and phase at m:n=10:50 is defined as the phase change. Referring to c of FIG. 4, the phase change-frequency curve of the resonant structure 21 employing the comb-like slits due to the movement of the polar plate 15 is shown. Referring to c of FIG. 5, a phase change-frequency curve of the resonant structure 21 using the strip-like slits due to the movement of the polar plate 15 is shown. As can be seen from c of FIG. 4 and c of FIG. 5, at the frequency point of 24.6 GHz, the phase change caused by the polar plate 15 moving 20 μm is about 71°.

Polarization conversion or polarization tuning of the electromagnetic wave by the modulation unit can be achieved by the phase change caused by the movement of the polar plate 15. To achieve polarization tuning, in some embodiments, as shown in FIG. 2, at least one resonant structure 21 includes a first resonant structure 31 and a second resonant structure 32, the extension direction of the slit 13 located in the first resonant structure 31 is a first direction f1 and the extension direction of the slit 13 located in the second resonant structure 32 is a second direction f2, the first direction f1 and the second direction f2 are perpendicular to each other.

As shown in FIG. 2, the first driving structure 33 is the driving structure 16 located within the first resonant structure 31 and the second driving structure 34 is the driving structure 16 located within the second resonant structure 32.

In particular implementations, a first driving signal may be provided to the first driving structure 33 and a second driving signal may be provided to the second driving structure 34, so that the phase change of the electromagnetic wave through the first resonant structure 31 is different from the phase change of the electromagnetic wave through the second resonant structure 32, to change the polarization state of the electromagnetic wave.

Illustratively, as shown in FIG. 2, the first resonant structure 31 and the second resonant structure 32 are within the same modulation unit 20, respectively near two mutually perpendicular sides of the modulation unit 20. With regard to the modulation unit 20 shown in FIG. 2, a first driving signal can be provided to the driving structure 16 (namely, the first driving structure 33) located in the first resonant structure 31, to drive the polar plate 15 located in the first resonant structure 31 to displace, for example, 20 μm, moving from m:n=30:30 to m:n=10:50, generating a phase change φ1 of an electromagnetic wave transmitted through the first resonant structure 31. A second driving signal can be provided to the driving structure 16 (namely, the second driving structure 34) located in the second resonant structure 32, driving the polar plate 15 located in the second resonant structure 32 to displace, for example, 0 μm, keeping m:n=30:30, so that an electromagnetic wave transmitted through the second resonant structure 32 generates a phase change φ2. That is, the phase difference between the electromagnetic wave transmitted through the first resonant structure 31 and the electromagnetic wave transmitted through the second resonant structure 32 is φ1−φ2. Wherein the phase changes φ1 and φ2 may be greater than 0° and less than π.

By adjusting the magnitude of the first driving signal and the second driving signal, the magnitude of the phase difference φ1−φ2 can be controlled, so that the conversion of the polarization state of an electromagnetic wave can be achieved. For example, a linearly polarized electromagnetic wave can be converted into an elliptically polarized electromagnetic wave or a circularly polarized electromagnetic wave, or the elliptically polarized electromagnetic wave or the circularly polarized electromagnetic wave can be converted into the linearly polarized electromagnetic wave.

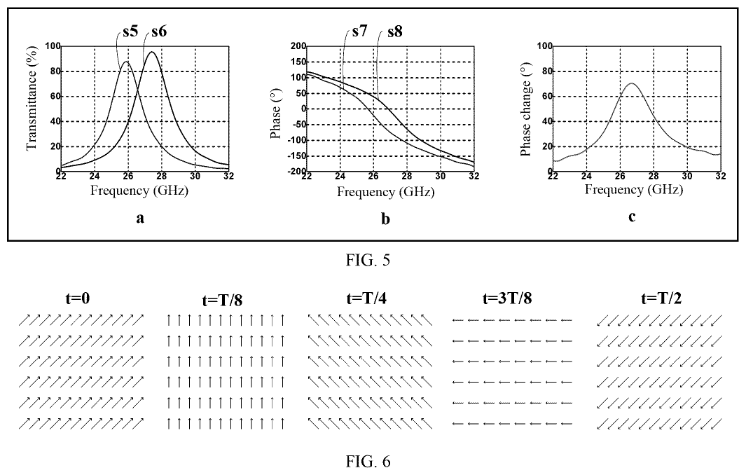

Referring to FIG. 6, a process of converting linearly polarized millimeter waves of 24.6 GHz into near-circularly polarized millimeter waves is shown. In FIG. 6, t represents time, T represents a millimeter wave vibration period, and an arrow represents a transmitted electric field vector. The viewing plane shown in FIG. 6 is a plane 12 mm from the exit surface of the modulation unit.

It should be noted that the extension direction of the slit 13 located in the first resonant structure 31 (i.e., the first direction f1) and the extension direction of the slit 13 located in the second resonant structure 32 (i.e., the second direction f2) may also intersect with each other, and the present disclosure is not limited thereto.

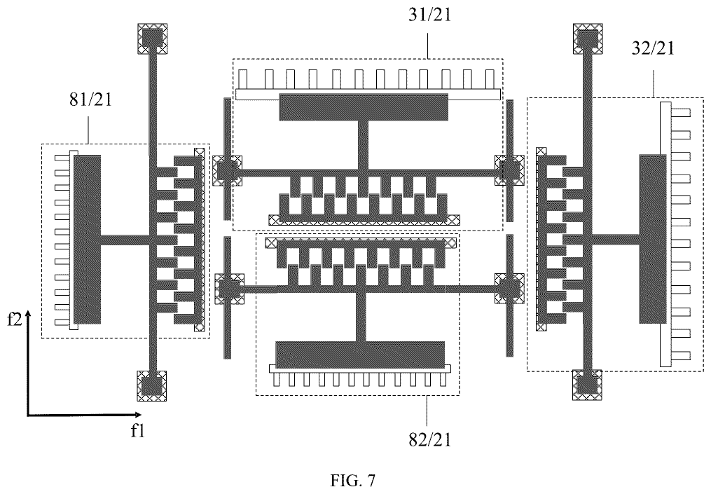

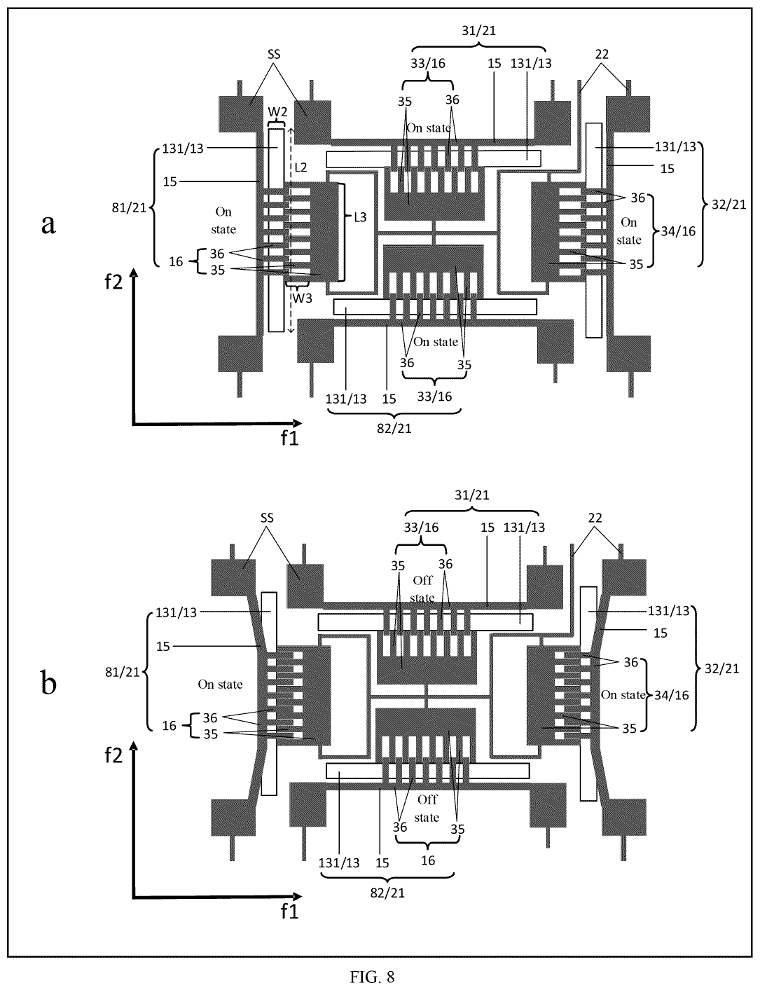

In some embodiments, as shown in FIG. 7 or FIG. 8, at least one resonant structure 21 further includes a third resonant structure 81 and a fourth resonant structure 82, wherein the operating frequency band of the first resonant structure 31 and the second resonant structure 32 is a first frequency band, and the operating frequency band of the third resonant structure 81 and the fourth resonant structure 82 is a second frequency band, and the first frequency band is different from the second frequency band.

By providing two sets of resonant structures 21, wherein one set of resonant structures 21 includes a first resonant structure 31 and a second resonant structure 32, and the other set of resonant structures 21 includes a third resonant structure 81 and a fourth resonant structure 82, the modulation unit can realize a dual-band polarization conversion, or extend the band range of the polarization conversion, since the operating frequency bands of the two sets of resonant structures 21 are different.

Wherein the first frequency band and the second frequency band may have no overlap or a partial overlap. Continuous polarization tuning can be achieved when the first frequency band partially overlaps the second frequency band.

In order to enable the third resonant structure 81 and the fourth resonant structure 82 to polar tune the transmitted electromagnetic wave, the extension direction of the slit 13 located in the third resonant structure 81 and the extension direction of the slit 13 located in the fourth resonant structure 82 may be perpendicular to each other (as shown in FIG. 7 or FIG. 8) or intersect with each other.

In practice, the slits 13 of the first set of resonant structures (including the first resonant structure 31 and the second resonant structure 32) may have the same shape and size and the polar plates 15 may have the same shape and size, and the slits 13 of the second set of resonant structures (including the third resonant structure 81 and the fourth resonant structure 82) may have the same shape and size and the polar plates 15 may have the same shape and size for design convenience.

In order to make the first frequency band different from the second frequency band, the parameters of the first group of resonant structures may be made different from the parameters of the second group of resonant structures, and the parameters may include at least one of the following: the size of the slit 13, the shape of the slit 13, the size of the polar plate 15, the shape of the polar plate 15, etc., which can influence the parameters of the resonant frequency of the resonant structure 21.

In particular implementations, the first resonant structure 31, the second resonant structure 32, the third resonant structure 81, and the fourth resonant structure 82 may be located in the same modulation unit 20 (as shown in FIG. 7 or FIG. 8) or may be located in different modulation units 20, and the present disclosure is not limited thereto.

As shown in FIG. 7 or FIG. 8, the first resonant structure 31 and the fourth resonant structure 82 are disposed close to two opposite sides of the modulation unit 20, respectively, and the second resonant structure 32 and the third resonant structure 81 are disposed close to the other two opposite sides of the modulation unit 20, respectively. Specifically, as shown in FIG. 7 or FIG. 8, the first resonant structure 31 is disposed close to the upper side of the modulation unit 20, the fourth resonant structure 82 is disposed close to the lower side of the modulation unit 20, the second resonant structure 32 is disposed close to the right side of the modulation unit 20, and the third resonant structure 81 is disposed close to the left side of the modulation unit 20.

In some embodiments, the extension direction of the slit 13 located in the third resonant structure 81 is the second direction f2 and the extension direction of the slit 13 located in the fourth resonant structure 82 is the first direction f1.

As shown in FIG. 7 or FIG. 8, the extension direction of the slit 13 located in the fourth resonant structure 82 is the same as the extension direction of the slit 13 located in the first resonant structure 31, both are the first direction f1. The extension direction of the slit 13 located in the second resonant structure 32 is the same as the extension direction of the slit 13 located in the third resonant structure 81, and both are the second direction f2. In this way, the space of the modulation unit 20 can be fully utilized, and the four resonant structures 21 can be compactly provided in a limited space so that the miniaturization of the modulation unit can be facilitated.

In some embodiments, the orthographic projection of the first resonant structure 31 on the base plate 10 and the orthographic projection of the fourth resonant structure 82 on the base plate 10 at least partially overlap in the first direction f1, so that the space of the modulation unit 20 in the first direction f1 can be fully utilized, facilitating miniaturization of the modulation unit.

Illustratively, as shown in FIG. 7 or FIG. 8, in the first direction f1, the orthographic projection of the first resonant structure 31 on the base plate 10 completely covers the orthographic projection of the fourth resonant structure 82 on the base plate 10.

In some embodiments, in the second direction f2, the orthographic projection of the second resonant structure 32 on the base plate 10 and the orthographic projection of the third resonant structure 81 on the base plate 10 at least partially overlap, so that the space of the modulation unit 20 in the second direction f2 can be fully utilized, facilitating miniaturization of the modulation unit.

Illustratively, as shown in FIG. 7 or FIG. 8, in the second direction f2, the orthographic projection of the second resonant structure 32 on the base plate 10 completely covers the orthographic projection of the third resonant structure 81 on the base plate 10.

In some embodiments, referring to FIG. 1 and FIG. 2, the distance h1 between the polar plate 15 and the base plate 10 is less than or equal to the width of the slit 13, the width of the slit 13 is the dimension of the slit 13 perpendicular to its extension direction. Further, the distance h1 between the polar plate 15 and the base plate 10 is less than or equal to the width W2 of the strip-like slit 131.

Illustratively, the distance h1 between the polar plate 15 and the base plate 10, i.e., the overhang height h1 of the polar plate 15 on the base plate 10, may be greater than or equal to 0.5 μm and less than or equal to 5 μm. To reduce etch thickness and process complexity, the distance h1 between the polar plate 15 and the base plate 10 may be greater than or equal to 1 micron and less than or equal to 2 μm.

In some embodiments, as shown in FIG. 2 or FIG. 3, the length L2 of the slit 13 is less than or equal to λ₁/2n₁ in the extension direction of the slit 13, λ₁ is the operating wavelength of the resonant structure 21 to which the slit 13 belongs, n₁ is the equivalent refractive index of the material filling and surrounding the slit 13.

In particular implementations, the length L2 of the slit 13 can be, for example, a few tens of nanometers, a few tens of micrometers, or a few hundreds of micrometers, etc., and can be specifically determined according to the operating band of the resonant structure 21 to which the slit 13 belongs.

In practice, the orthographic projection of the polar plate 15 on the base plate 10 can be located anywhere in the slit 13, in the same resonant structure 21, and in the extension direction of the slit 13. In order to improve the tuning sensitivity, in some embodiments, as shown in FIG. 2 or FIG. 3, in the same resonant structure 21, the orthographic projection of the polar plate 15 on the base plate 10 is centered on the slit 13 in the extension direction of the slit 13.

The inventors have found that the polar plate 15 connected to the driving structure 16 cannot be oversized, and if the polar plate 15 is oversized, the weight of the polar plate 15 will increase, which on the one hand will result in that the driving structure 16 needs to use a larger drive voltage to drive the polar plate 15, and on the other hand is suspended below the polar plate 15, so that the polar plate 15 will collapse and deform if the polar plate 15 is too heavy. In some embodiments, in the same resonant structure 21, the ratio of the length LI of the polar plate 15 to the length L2 of the slit 13 is greater than or equal to ⅓ and less than or equal to 4/3 in the extension direction of the slit 13, as shown in FIG. 2 or FIG. 3.

To further reduce the weight of the polar plate 15, the above ratio may be greater than or equal to ⅓ and less than or equal to 1 or ½.

In some embodiments, as shown in FIG. 2, in the direction perpendicular to the extension direction of the slit 13, the width W1 of the polar plate 15 may be larger than or equal to the width W2 of the strip-like slit 131, so that the tuning range of the frequency and phase on the one hand and the sensitivity of the resonant frequency of the resonant structure 21 to the movement of the polar plate 15 on the other hand may be improved.

In some embodiments, the thickness of polar plate 15 (i.e., the dimension of the polar plate 15 in the normal direction of the substrate 11) may be greater than or equal to 0.5 μm and less than or equal to 50 μm. Further, the polar plate 15 may have a thickness greater than or equal to 3 μm and less than or equal to 5 μm. In particular implementations, the thickness of the polar plate 15 may be determined based on the support of the driving structure 16 and the state of the art, and the present disclosure is not particularly limited.

In order to further compress the size of the modulation unit, in some embodiments, in the same resonant structure 21, if the length L2 of the slit 13 is greater than or equal to the length L3 of the driving structure 16 in the extension direction of the slit 13, then the polar plate 15 is provided close to the edge of the modulation unit 20, and the driving structure 16 is located on the side of the polar plate 15 away from the edge of the modulation unit 20, as shown in FIG. 2. If, in the extension direction of the slit 13, the length L2 of the slit 13 is less than or equal to the length L3 of the driving structure 16, the driving structure 16 is provided close to the edge of the modulation unit 20 and the polar plate 15 is located on the side of the driving structure 16 away from the edge of the modulation unit 20.

In some embodiments, as shown in FIG. 2, the driving structure 16 includes a MEMS switch. Here, the MEMS switch is a micro-electro-mechanical system (MEMS) switch. In the present disclosure, the MEMS switch may be an electrostatically driven cantilever beam type switch for switching on/off low-frequency electrical signals, and may also be a microswitch that utilizes relative translational movement between the stator comb-like electrode and the mover comb-like electrode to effect switching.

The application frequencies of MEMS switches range from low frequencies to microwave, millimeter wave, and optical bands. Potential applications of the MEMS switch in radio frequency systems include antenna transceiver and signal filtering path selection and interconnection, electronically controlled phase shifting units, smart antennas, reconfigurable meta surfaces, etc. in multi-band communication systems. The requirements for the electronically controlled reconfigurable antenna for the MEMS switch are: the switching loss is small, the insertion loss is small when the switch is in the on state, the isolation is large when the switch is in the off state, the driving voltage of the switch is small, the switching speed is fast, etc.

In some embodiments, as shown in FIG. 2, the MEMS switch includes a stator comb-like electrode 35 and a mover comb-like electrode 36 which are oppositely provided in the moving direction of the polar plate 15. Wherein the comb ridge of the stator comb-like electrode 35 is fixed on the base plate 10, the comb teeth of the stator comb-like electrode 35 face the mover comb-like electrode 36, the comb teeth of the mover comb-like electrode 36 face the stator comb-like electrode 35, two ends of the comb ridge of the mover comb-like electrode 36 are fixed on the base plate 10, and one side surface of the comb ridge of the mover comb-like electrode 36 away from the comb teeth is connected to the polar plate 15 via a cantilever beam 37.

The stator comb-like electrode 35 and the mover comb-like electrode 36 are used for generating an electrostatic force under the action of the driving signal, and the mover comb-like electrode 36 drives the polar plate 15 to move under the action of the electrostatic force.

As shown in FIG. 2, the support structure 19 includes a first support pattern 23 and a second support pattern 24, wherein the first support pattern 23 is located between the comb ridge of the stator comb-like electrode 35 and the base plate 10 for fixing the comb ridge of the stator comb-like electrode 35 on the base plate 10. The second support patterns 24 are located between the two ends of the comb ridges of the mover comb-like electrodes 36 and the base plate 10 and are used for fixing the two ends of the comb ridges of the mover comb-like electrodes 36 (namely, the fixed ends SS) on the base plate 10. The gap h1 is located between the polar plate 15 and the base plate 10, between the cantilever beam 37 and the base plate 10, between the middle region of the comb ridge of the mover comb-like electrode 36 and the base plate 10 and between the comb teeth of the mover comb-like electrode 36 and the base plate 10, and may also be located between the comb teeth of the stator comb-like electrode 35 and the base plate 10. Here, the middle region of the comb ridge of the mover comb-like electrode 36 refers to the comb ridge portion located between the two fixed ends SS.

As shown in FIG. 2, the comb teeth of the stator comb-like electrode 35 and the comb teeth of the mover comb-like electrode 36 are parallel to each other and staggered. The mover comb-like electrode 36 is connected to the drive line 22, and under the action of a driving signal input by the drive line 22, the mover comb-like electrode 36 can be close to the stator comb-like electrode 35 or away from the stator comb-like electrode 35 so as to drive the polar plate 15 to translate.

In the related art, a single mover comb-like electrode 36 translates the polar plate 15 a distance of approximately 10 μm to 25 μm.

Referring to FIG. 2, the comb ridge length L3 of the stator comb-like electrodes 35 and the mover comb-like electrodes 36 may be on the order of millimeters, and the comb teeth length W3 may be on the order of tens of micrometers to 100 micrometers.

Illustratively, stator comb-like electrodes 35 and mover comb-like electrodes 36 have a comb teeth length W3 of about 50 μm, a comb teeth width of about 10 μm, and a comb ridge length L3 of about 1.0 millimeter.

There is a gap between the cantilever beam 37 and the base plate 10, which has certain rigidity and serves to support the polar plate 15.

In some embodiments, as shown in FIG. 8, the comb ridges of the mover comb-like electrodes 36 are reused as polar plates 15. In this implementation, the tuning of the frequency, phase, and polarization of the electromagnetic wave is achieved directly by the movement of the mover comb-like electrode 36 over the slit 13.

In FIG. 8, the comb teeth of the stator comb-like electrode 35 face the mover comb-like electrode 36, the comb teeth of the mover comb-like electrode 36 face the stator comb-like electrode 35, and since the comb ridges of the mover comb-like electrode 36 are reused as the polar plate 15, there is no need to additionally provide the substrate 15 and the cantilever beam 37, facilitating the miniaturization of the modulation unit. In FIG. 8, the stator comb-like electrodes 35 and the mover comb-like electrodes 36 can be fixed on the base plate 10 in the same manner as in FIG. 2, and reference can be made in particular to the description of FIG. 2, which will not be repeated here.

Illustratively, as shown in FIG. 8, the slit 13 is shaped as a strip (131 as shown in FIG. 8), and an orthographic projection of the comb teeth of the stator comb-like electrode 35 on the base plate 10 abuts one side of the strip-like slit 131. In FIG. 8, the stator comb-like electrode 35 has a comb ridge length L3 of 600 μm, a comb teeth length W3 of 50 μm, a comb teeth width of 12 μm, and a comb teeth period of 30 μm. The width W2 of the strip-like slit 131 is 30 μm, and the length L2 of the strip-like slit 131 is 4.4 mm. The comb teeth of the mover comb-like electrode 36 have an overhang height h1 of 3 μm.

In a particular implementation, the mover comb-like electrode 36 moves over the slit 13 driven by a driving signal to form an on state (such as any of the resonant structures 21 in the modulation unit shown in a of FIG. 8) and an off state (such as the second resonant structure 32 and the third resonant structure 81 in the modulation unit shown in b of FIG. 8).

In the on state, the orthographic projection of the comb ridge of the mover comb-like electrode 36 (i.e. the polar plate 15) on the base plate 10 may not cover the strip-like slit 131, as in any of the resonant structures 21 in the modulation unit shown in a of FIG. 8, and the comb teeth of the mover comb-like electrode 36 and the comb teeth of the stator comb-like electrode 35 may partially overlap, as in a of FIG. 8, overlapped by 10 μm.

In the off state, as shown in the second resonant structure 32 and the third resonant structure 81 in the modulation unit shown in b of FIG. 8, the comb teeth of the mover comb-like electrode 36 move towards the stator comb-like electrode 35 close to, for example, 20 μm, the overlapping length of the comb teeth reaches 30 μm, and after the movement, the orthographic projection of the comb ridge (namely, the polar plate 15) of the mover comb-like electrode 36 on the base plate 10 at least partially covers the slit 13.

It should be noted that, in the on state, the distance between the comb ridge of the mover comb-like electrode 36 and the slit 13 needs to be smaller than the moving distance of the mover comb-like electrode 36 to ensure that the mover comb-like electrode 36, after moving, at least partially covers the slit 13. In a of FIG. 8, the distance between the comb ridge of the mover comb-like electrode 36 and the slit 13 is about 10 μm in the on state.

Referring to a of FIG. 9, which shows the transmission versus frequency curves for the resonant structure 21 of FIG. 8 in the on state and the off state. Wherein the transmittance-frequency curve in the on state is s9, and the transmittance-frequency curve in the off state is s10. It can be seen that the electromagnetic waves can be frequency-tuned by reusing the comb ridges of the mover comb-like electrodes 36 as the polar plates 15. Since the comb teeth of the mover comb-like electrode 36 are directly located above the slit 13, the transmittance of electromagnetic waves is relatively low, but the transmittance peak can still reach 60%.

As shown in FIG. 8, when the modulation unit 20 includes the first resonant structure 31 and the second resonant structure 32, a phase difference of approximately 75° can be obtained at 26.5 GHz using the frequency offset between the on state and the off state (as shown in b of FIG. 9), and the polarization of the electromagnetic wave can be adjusted using the phase difference.

In some embodiments, the polar plate 15, the mover comb-like electrode 36, the stator comb-like electrode 35, and the cantilever beam 37 are disposed in the same layer and of the same material. In this way, the polar plate 15, the mover comb-like electrode 36, the stator comb-like electrode 35, and the cantilever beam 37 can be formed simultaneously using the same process, thereby simplifying the process flow.

Illustratively, the polar plate 15, the mover comb-like electrode 36, the stator comb-like electrode 35, and the cantilever beam 37 may include the same metallic material, such as a molybdenum/neodymium/molybdenum material.

Wherein the driving signal provided to the driving structure 16 may include a reference voltage provided to the stator comb-like electrode 35 and a driving voltage provided to the mover comb-like electrode 36. The reference voltage may be a fixed voltage (e.g., ground potential), in which case the drive lines 22 connecting the plurality of stator comb-like electrodes 35 may communicate with each other (as shown in FIG. 8), and the present disclosure is not limited thereto.

To enable independent control of each driving structure 16, the drive lines 22 connecting the plurality of mover comb-like electrodes 36 may be independent of each other (as shown in FIG. 7 and FIG. 8) or may communicate with each other according to actual needs, and the present disclosure is not limited thereto.

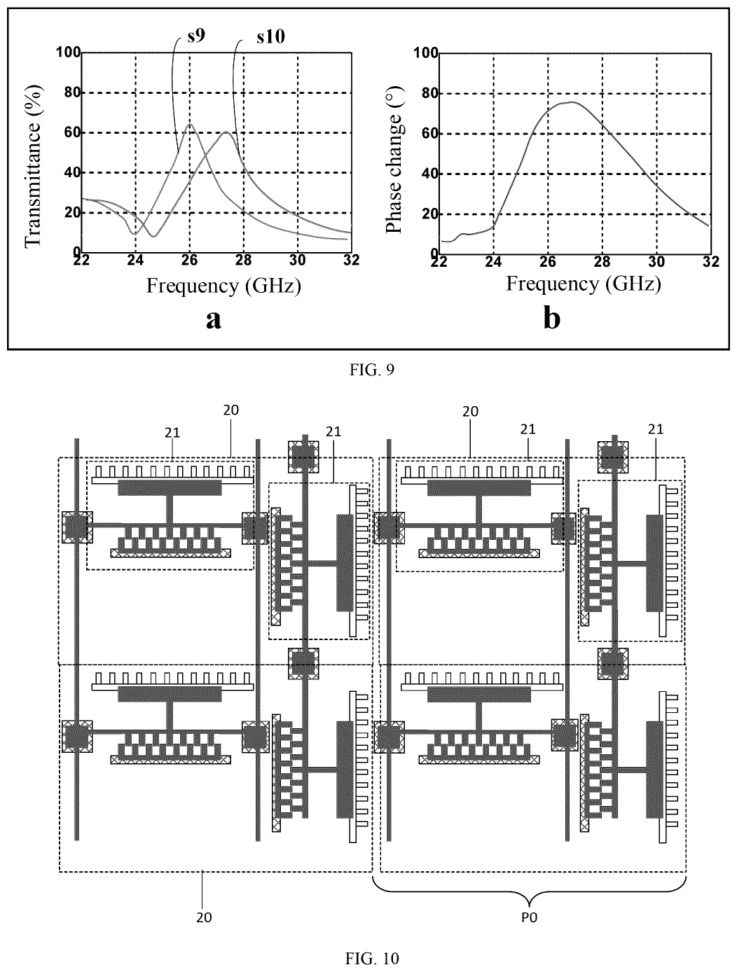

The present disclosure provides a modulation device including a modulation panel 90, as shown in FIG. 10, the modulation panel 90 includes at least one modulation unit 20 as provided in any of the embodiments.

As will be appreciated by those skilled in the art, the modulation device has the advantage of the modulation unit 20.

Among them, the modulation panel may include one or more modulation units 20, and each modulation unit 20 may include one or more resonant structures 21. In FIG. 10, the modulation panel 90 includes a plurality of modulation units 20 arrayed in a row direction and a column direction, each modulation unit 20 including two resonant structures 21.

In some embodiments, as shown in FIG. 10, the arrangement period PO of the modulation units 20 of the array arrangement may be less than λ₂/2, λ₂ is the operating wavelength of the modulation device. A plurality of sub-wavelength scale modulation units 20 are provided in an array to form a meta surface array.

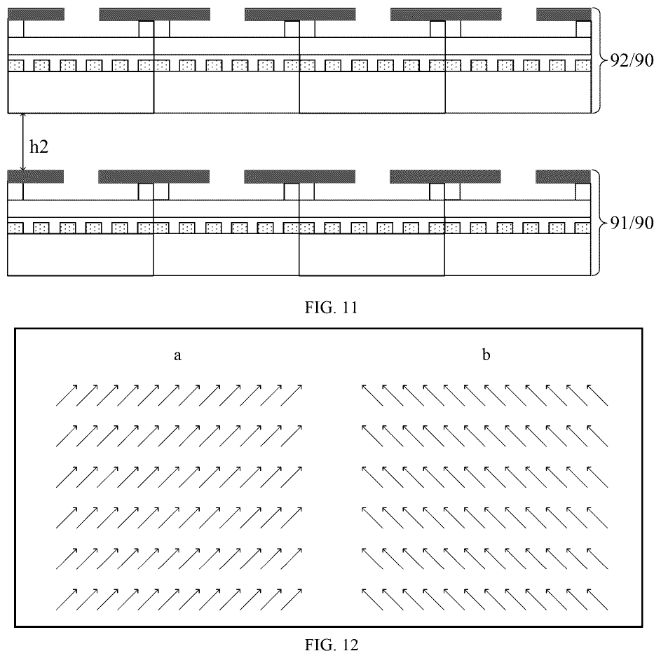

In some embodiments, as shown in FIG. 11, the modulation device includes a plurality of modulation panels 90 arranged in stacked and spaced apart from each other. The spacing between two adjacent modulation panels 90 is h2.

When the modulation unit 20 in the modulation panel 90 includes the first resonant structure 31 and the second resonant structure 32, the modulation panel 90 is capable of polarization conversion of the incident electromagnetic wave to change the polarization state of the electromagnetic wave. In this way, a plurality of modulation panels 90 arranged in stacked can convert the polarization state of an incident electromagnetic wave multiple times.

As shown in FIG. 11, the modulation device includes a first modulation panel 91 and a second modulation panel 92 which are arranged in stacked and are spaced apart from each other, and the modulation unit 20 in the first modulation panel 91 and the modulation unit 20 in the second modulation panel 92 are both as shown in FIG. 2, and include at least a first resonant structure 31 and a second resonant structure 32.

In a specific implementation, referring to FIG. 11 and FIG. 2, the same or different first driving signals may be supplied to the first driving structure 33 located in the first modulation panel 91 and the second modulation panel 92, respectively, and the same or different second driving signals may be supplied to the second driving structure 34 located in the first modulation panel 91 and the second modulation panel 92, respectively, so that the electromagnetic wave passing through the first modulation panel 91 is converted from the first polarization state to the second polarization state, and the electromagnetic wave passing through the second modulation panel 92 is converted from the second polarization state to the third polarization state.

When the structures of the first modulation panel 91 and the second modulation panel 92 are the same, and the same first driving signal is provided to the first driving structure 33 located in the first modulation panel 91 and the second modulation panel 92, respectively, and the same second driving signal is provided to the second driving structure 34 located in the first modulation panel 91 and the second modulation panel 92, respectively, it is possible to generate a phase difference ψ1 after the electromagnetic wave passes through the first resonant structure 31 and the second resonant structure 32 in the first modulation panel 91, and also generate a phase difference ψ1 after the electromagnetic wave passes through the first resonant structure 31 and the second resonant structure 32 in the second modulation panel 92. Here, the phase change ψ1 may be larger than 0° and smaller than π.

In some embodiments, the first polarization state and the third polarization state may be linear polarizations with different electric vector vibration directions, and the second polarization state is elliptical polarization or circular polarization. When the above-mentioned phase difference ψ1=π/2, the first polarization state (as shown in a in FIG. 12) and the third polarization state (as shown in b in FIG. 12) are linear polarizations whose electric vector vibration directions are perpendicular to each other, and the second polarization state is circular polarization.

In some embodiments, the first polarization state and the third polarization state are elliptical polarization or circular polarization with different electric vector rotation directions (or different chirality), and the second polarization state is linear polarization. When the above-mentioned phase difference ψ1=π/2, the first polarization state is left-hand circular polarization and the third polarization state is right-hand circular polarization, or the first polarization state is right-hand circular polarization and the third polarization state is left-hand circular polarization.

To reduce the insertion loss of the modulation device, in some embodiments, as shown in FIG. 11, the spacing h2 between two adjacent modulation panels 90 is greater than or equal to λ₂/2n₂, λ₂ is the operating wavelength of the modulation device, and n₂ is the refractive index of the material filled between the two adjacent modulation panels 90.

By setting the spacing between two adjacent modulation panels 90 to be greater than or equal to λ₂/2n₂, so that the electromagnetic wave transmitted through the previous modulation panel 90 can be incident on the next modulation panel 90 in the form of a plane wave, the transmittance of the electromagnetic wave transmitted through the modulation device can be increased, and the insertion loss of the modulation device can be reduced.

It should be noted that the spacing h2 between two adjacent modulation panels 90 may also be less than λ₂/2n₂, which is not a limitation of the present disclosure.

The modulation device provided by the present disclosure may be, for example, an antenna, and may also be a product or component that includes an antenna, such as a cell phone, tablet computer, television, notebook computer, digital photo frame, navigator, etc.

Wherein the antenna may further include a transmission module and the transmission module is used for transmitting a radio frequency signal. Specifically, the radio frequency signal can be transmitted to the transmitting module after being frequency, phase, or polarization modulated by the modulation device.

The present disclosure provides a driving method applied to a modulation device as provided in any of the embodiments, and referring to FIG. 2, the driving method includes:

Step S01: providing a driving signal to the driving structure 16, so that the driving structure 16 drives the polar plate 15 to move in response to the driving signal, to change the size of the overlap region of the orthographic projection of the polar plate 15 on the base plate 10 with the slit 13, to adjust the resonant frequency of the resonant structure 21.

In some embodiments, referring to FIG. 2, when the at least one resonant structure 21 includes a first resonant structure 31 and a second resonant structure 32, and the extension direction of the slit 13 located in the first resonant structure 31 and the extension direction of the slit 13 located in the second resonant structure 32 are perpendicular to each other, in step S01, the step of providing a driving signal to the driving structure 16 includes:

Step S11: providing a first driving signal to the first driving structure 33, and providing a second driving signal to the second driving structure 34, so that a phase change generated by the electromagnetic wave passing through the first resonant structure 31 is different from a phase change generated by the electromagnetic wave passing through the second resonant structure 32, to change the polarization state of the electromagnetic wave.

The first driving structure 33 is a driving structure 16 located in the first resonant structure 31 and the second driving structure 34 is a driving structure 16 located in the second resonant structure 32.

In some embodiments, referring to FIG. 11 and FIG. 2, when the modulation device includes a first modulation panel 91 and a second modulation panel 92 arranged in stacked and spaced apart from each other, in step S11, the step of providing a first driving signal to the first driving structure 33 and providing a second driving signal to the second driving structure 34 includes:

Step S21: providing the same or different first driving signals to the first driving structure 33 located in the first modulation panel 91 and the second modulation panel 92, respectively, and providing the same or different second driving signals to the second driving structure 34 located in the first modulation panel 91 and the second modulation panel 92, respectively, so that the electromagnetic wave passing through the first modulation panel 91 is converted from the first polarization state to the second polarization state, and the electromagnetic wave passing through the second modulation panel 92 is converted from the second polarization state to the third polarization state.

In some embodiments, the first polarization state and the third polarization state are linear polarizations with different electric vector vibration directions, and the second polarization state is elliptical polarization or circular polarization.

In some embodiments, the first polarization state and the third polarization state are elliptical polarization or circular polarization with different electric vector rotation directions, and the second polarization state is the linear polarization.

It should be noted that the driving method may include further steps, which may be determined according to actual requirements, and the present disclosure is not limited thereto. Reference can be made to the above description of the modulation unit or modulation device embodiments for a detailed description and technical effects of the driving method, which will not be repeated here.

The present disclosure provides a preparation method of a modulation unit, referring to FIG. 1, the preparation method includes:

Step S31: providing a base plate 10, wherein the base plate 10 includes: a substrate 11, and a metal layer 12 provided on one side of the substrate 11, the metal layer 12 is provided with a slit 13.

Step S32: forming a driving layer 14 on one side of the base plate 10 to obtain a modulation unit; wherein the driving layer 14 includes a polar plate 15 and a driving structure 16, with a gap h1 between the polar plate 15 and the base plate 10, and the modulation unit includes at least one resonant structure 21, and the resonant structure 21 includes: a slit 13, a polar plate 15 and a driving structure 16, within the same resonant structure 21, the driving structure 16 is connected to the polar plate 15 for driving the polar plate 15 to move in response to a driving signal to change a size of an overlap region of an orthographic projection of the polar plate 15 on the base plate 10 and the slit 13 to adjust a resonant frequency of the resonant structure 21.

The modulation unit provided in any of the above embodiments can be prepared using the preparation method provided in the present disclosure.

In some embodiments, as shown in FIG. 2, the driving structure 16 includes a MEMS switch, and the MEMS switch includes: a stator comb-like electrode 35 and a mover comb-like electrode 36 which are oppositely provided in the moving direction of the polar plate 15, wherein the comb teeth of the stator comb-like electrode 35 face the mover comb-like electrode 36, the comb teeth of the mover comb-like electrode 36 face the stator comb-like electrode 35, and one side surface of the comb ridges of the mover comb-like electrode 36 away from the comb teeth is connected to the polar plate 15 via a cantilever beam 37. Referring to FIG. 1, step S31 may specifically include:

Step S41: providing a substrate 11.

Step S42: forming a metal layer 12 on one side of the substrate 11, and the metal layer 12 is provided with a slit 13.

Step S43: forming a planar layer 17 and a passivation layer 18 successively on the side of the metal layer 12 away from the substrate 11, are to obtain the base plate 10.

Step S32 may specifically include:

Step S44: forming a sacrificial layer 143 on the side of the passivation layer 18 away from the substrate 11.

Step S45: using a patterning process to form a driving layer 14 on the side of the sacrificial layer 143 away from the substrate 11, wherein the driving layer 14 includes the polar plate 15, the mover comb-like electrode 36, the stator comb-like electrode 35 and the cantilever beam 37.

Step S46: etching the sacrificial layer 143 to form the support structure 19 and the gap h1. Referring to FIG. 2, the support structure 19 includes a first support pattern 23 and a second support pattern 24. Wherein the first support pattern 23 is located between the comb ridge of the stator comb-like electrode 35 and the base plate 10 for fixing the comb ridge of the stator comb-like electrode 35 on the base plate 10; the second support pattern 24 is located between two ends of the comb ridge of the mover comb-like electrode 36 (namely, a fixed end SS) and the base plate 10, and is used for fixing the two ends of the comb ridge of the mover comb-like electrode 36 on the base plate 10; the gap h1 is located at least between the polar plate 15 and the base plate 10, between the cantilever beam 37 and the base plate 10, between the comb ridge intermediate region of the mover comb-like electrode 36 and the base plate 10, and between the comb teeth of the mover comb-like electrode 36 and the base plate 10.

Illustratively, as shown in FIG. 13, the preparation method of the modulation unit may specifically include the following steps:

Step 1: a metal layer 12 is patterned on the substrate 11, the metal layer 12 is provided with slits 13.

Step 2: on the side of the metal layer 12 away from the substrate 11, a planar layer 17 and a passivation layer 18 are successively formed to obtain the base plate 10.

Step 3: a sacrificial layer 143 is formed on the side of the passivation layer 18 away from the substrate 11.

Step 4: silicon material 148 is evaporated on the side of the sacrificial layer 143 away from the substrate 11.

Step 5: the silicon material 148 is crystallized and ion-doped at a high concentration to obtain a highly doped crystallized silicon material 147.

Step 6: a conductive material 146 is formed on the side of the highly doped crystallized silicon material 147 away from the substrate 11, to obtain a driving material layer 144.

Step 7: using an exposure development process, a photoresist pattern 145 is formed on the side of the driving material layer 144 away from the substrate 11.

Step 8: the exposed driving material layer 144 is etched to remove the photoresist pattern 145 to form the driving layer 14. The driving layer 14 includes a highly doped crystallized silicon layer 141 and a conductive layer 142, the highly doped crystallized silicon layer 141 is located on the side of the conductive layer 142 close to the base plate 10. By providing a highly doped crystallized silicon layer 141, the stability and reliability of the resonant structure 21 can be improved.

Step 9: the sacrificial layer 143 under the driving layer 14 is etched to form a support structure 19 (including a first support pattern 23 and a second support pattern 24) and a gap h1, resulting in a modulation unit.

It should be noted that the highly doped crystallized silicon material 147 is not necessary, and in steps 4 to 6, the conductive material 146 may be formed directly on the side of the sacrificial layer 143 away from the substrate 11, resulting in the driving material layer 144. The driving layer 14 thus prepared includes the conductive layer 142 and does not include the highly doped crystallized silicon layer 141 so that the process flow can be simplified.

In the present disclosure, “a plurality of” means two or more, and “at least one” means one or more, unless otherwise specified.

In the present disclosure, the terms “up”, “down”, etc. indicate orientation or positional relationships based on the orientation or positional relationships shown in the accompanying drawings, only for the convenience of describing and simplifying the description of the present disclosure, and not to indicate or imply that the device or component referred to must have a specific orientation, be constructed and operated in a specific orientation, and therefore cannot be understood as a limitation of the present disclosure.

In the specification, the terms “comprising”, “including”, or any other variation thereof are intended to encompass non-exclusive inclusion, such that a process, method, product, or equipment that includes a series of elements not only includes those elements, but also includes other elements not explicitly listed, or also includes elements inherent to such process, method, product, or equipment. Without further limitations, the elements limited by the statement “including one . . . ” do not exclude the existence of other identical elements in the process, method, commodity, or device that includes the said elements.

The terms “one embodiment”, “some embodiments”, “exemplary embodiments”, “one or more embodiments”, “examples”, “one example”, “some examples”, etc. referred to in the specification are intended to indicate that specific features, structures, materials, or characteristics related to the embodiment or example are included in at least one embodiment or example disclosed herein. The schematic representation of the above terms may not necessarily refer to the same embodiment or example. Furthermore, the specific features, structures, materials, or features described may be included in any one or more embodiments or examples in any appropriate manner.

In the specification, relational terms such as first and second are only used to distinguish one entity or operation from another entity or operation, without necessarily requiring or implying any such actual relationship or order between these entities or operations.

When describing some embodiments, the expressions “coupled” and “connected” may be used. For example, when describing some embodiments, the term “connection” may be used to indicate direct physical or electrical contact between two or more components. For example, when describing some embodiments, the term “coupled” may be used to indicate direct physical or electrical contact between two or more components. However, the terms “coupled” or “communicatively coupled” may also refer to two or more components that do not have direct contact with each other but still cooperate or interact with each other. The disclosed embodiments here are not necessarily limited to the content of the specification.

“At least one of A, B, and C” has the same meaning as “at least one of A, B, or C” and includes the following combinations of A, B, and C: only A, only B, only C, a combination of A and B, a combination of A and C, a combination of B and C, and a combination of A, B, and C.

“A and/or B” includes the following three combinations: only A, only B, and a combination of A and B.

As used in the specification, the term “if” is optionally interpreted as meaning “when” or “at” or “in response to determination” or “in response to detection” depending on the context. Similarly, depending on the context, the phrases “if determined . . . ” or “if detected [stated condition or event]” are optionally interpreted as referring to “when determined . . . ” or “in response to determined . . . ” or “when detected [stated condition or event]” or “in response to detected [stated condition or event]”.

The use of “used” or “configured as” in the specification implies an open and inclusive language, which does not exclude devices that are applicable or configured to perform additional tasks or steps.

The use of “based on” or “based on” in the specification implies openness and inclusiveness. A process, step, calculation, or other action based on one or more of the conditions or values may be based on other conditions or exceed the values in practice. In practice, a process, step, calculation, or other action based on one or more of the conditions or values may be based on other conditions or exceed the values.

As used in the specification, “approximately”, “roughly”, or “similar” includes the value described and the average value within an acceptable deviation range of a specific value, where the acceptable deviation range is determined by ordinary technical personnel in the art taking into account the measurement being discussed and the errors associated with a specific amount of measurement (i.e., limitations of the measurement system).

As used in the specification, “parallel”, “vertical”, “equal”, and “even” include the situation described and situations that are similar to the situation described, and the range of such similar situations is within an acceptable deviation range, The acceptable deviation range is determined by those skilled in the art, taking into account the measurement being discussed and the errors related to a specific amount of measurement (i.e., the limitations of the measurement system). For example, “parallel” includes absolute parallel and approximate parallel, where the acceptable deviation range for approximate parallel can be within 5°. “Vertical” includes absolute vertical and approximate vertical, where the acceptable deviation range for approximate vertical can also be within 5°. “Equal” includes absolute equality and approximate equality, where the acceptable deviation range of approximate equality, for example, can be equal. The difference between the two is less than or equal to 5% of either. “Even” includes absolute flush and approximate flush, where the acceptable deviation range for approximate flush, for example, can be that the distance between the two is less than or equal to 5% of the size of either.

It should be understood that when a layer or component is referred to as being on another layer or substrate, it can be that the layer or component is directly on another layer or substrate, or there can be an intermediate layer between the layer or component and another layer or substrate.

The specification describes exemplary embodiments with reference to sectional and/or floor plans as idealized exemplary drawings. In the attached figures, for clarity, the thickness of the layers and regions has been enlarged. Therefore, it can be assumed that changes in shape relative to the drawings may occur due to factors such as manufacturing technology and/or tolerances. Therefore, exemplary embodiments should not be interpreted as limited to the shape of the area shown herein, but rather include shape deviations caused by, for example, manufacturing. For example, the etched area shown as a rectangle will typically have curved features. Therefore, the areas shown in the drawings are essentially illustrative, and their shapes are not intended to show the actual shape of the region of the device, nor are they intended to limit the scope of exemplary embodiments.

Finally, it should be noted that the above embodiments are only used to illustrate the technical solution disclosed herein, and not to limit it. Although detailed explanations of the present disclosure have been provided with reference to the aforementioned embodiments, those skilled in the art should understand that they can still modify the technical solutions recorded in the aforementioned embodiments, or equivalently replace some of the technical features therein. And these modifications or replacements do not make the essence of the corresponding technical solutions deviate from the spirit and scope of the technical solutions disclosed in the present disclosure.

1. A modulation unit, comprising:
a base plate, comprising: a substrate, and a metal layer provided on one side of the substrate, wherein the metal layer is provided with a slit; and
a driving layer, provided on one side of the base plate, wherein the driving layer comprises a polar plate and a driving structure, and a gap is provided between the polar plate and the base plate;
wherein the modulation unit comprises at least one resonant structure comprising the slit, the polar plate, and the driving structure; and
in the same resonant structure, the driving structure is connected to the polar plate for driving the polar plate to move in response to a driving signal, to change a size of an overlap region of an orthographic projection of the polar plate on the base plate and the slit, to adjust a resonant frequency of the resonant structure.

2. The modulation unit according to claim 1, wherein in the same resonant structure, a moving direction of the polar plate and an extension direction of the slit are perpendicular to each other.

3. The modulation unit according to claim 1, wherein the slit comprises a strip-like slit, the extension direction of the slit is an extension direction of the strip-like slit.

4. The modulation unit according to claim 3, wherein the slit further comprises at least one branch slit, and the at least one branch slit and the strip-like slit are communicated and intersected with each other.

5. The modulation unit according to claim 4, wherein the at least one branch slit is located on a same side of the strip-like slit; and in the same resonant structure, orthographic projections of the driving structure and at least part of the polar plate on the base plate is located on a side of the strip-like slit away from the branch slit.

6. The modulation unit according to claim 1, wherein the at least one resonant structure comprises a first resonant structure and a second resonant structure, an extension direction of the slit located in the first resonant structure is a first direction, an extension direction of the slit located in the second resonant structure is a second direction, and the first direction and the second direction are perpendicular to each other.

7. The modulation unit according to claim 6, wherein the at least one resonant structure further comprises a third resonant structure and a fourth resonant structure, operating frequency bands of the first resonant structure and the second resonant structure are a first frequency band, operating frequency bands of the third resonant structure and the fourth resonant structure are a second frequency band, and the first frequency band is different from the second frequency band.

8. The modulation unit according to claim 7, wherein the extension direction of the slit located in the third resonant structure is the second direction, and the extension direction of the slit located in the fourth resonant structure is the first direction; and
in the first direction, an orthographic projection of the first resonant structure on the base plate and an orthographic projection of the fourth resonant structure on the base plate are at least partially overlapped;
in the second direction, an orthographic projection of the second resonant structure on the base plate and an orthographic projection of the third resonant structure on the base plate are at least partially overlapped.

9. The modulation unit according to claim 1, wherein a distance between the polar plate and the base plate is less than or equal to a width of the slit, and the width of the slit is a dimension of the slit in a direction perpendicular to an extension direction of the slit.

10. The modulation unit according to claim 1, wherein a length of the slit in an extension direction of the slit is less than or equal to λ₁/2n₁,λ₁ is an operating wavelength of a resonant structure to which the slit belongs, and n₁ is an equivalent refractive index of a material filling the slit and surrounding the slit.

11. The modulation unit according to claim 1, wherein in the same resonant structure, the orthographic projection of the polar plate on the base plate is centrally located in the slit along an extension direction of the slit.

12. The modulation unit according to claim 1, wherein in the same resonant structure, a ratio between a length of the polar plate and a length of the slit is greater than or equal to ⅓ and less than or equal to 4/3 along an extension direction of the slit.

13. The modulation unit according to claim 1, wherein the driving structure comprises a MEMS switch, the MEMS switch comprises a stator comb-like electrode and a mover comb-like electrode which are oppositely provided in a moving direction of the polar plate;
wherein a comb ridge of the stator comb-like electrode is fixed on the base plate, comb teeth of the stator comb-like electrode face the mover comb-like electrode, comb teeth of the mover comb-like electrode face the stator comb-like electrode, two ends of a comb ridge of the mover comb-like electrode are fixed on the base plate, and one side surface of the comb ridge of the mover comb-like electrode away from the comb teeth of the mover comb-like electrode is connected to the polar plate via a cantilever beam; and
the stator comb-like electrode and the mover comb-like electrode are used for generating an electrostatic force under action of the driving signal, and the mover comb-like electrode drives the polar plate to move under action of the electrostatic force.

14. The modulation unit according to claim 13, wherein the comb ridge of the mover comb-like electrode is reused as the polar plate.

15. The modulation unit according to claim 13, wherein the polar plate, the mover comb-like electrode, the stator comb-like electrode, and the cantilever beam are provided in a same layer and of a same material.

16. The modulation unit according to claim 1, wherein the driving layer comprises at least one of a conductive layer and a highly doped crystallized silicon layer provided on a side of the conductive layer close to the base plate.

17. A modulation device, comprising a modulation panel, wherein the modulation panel comprises the at least one modulation unit according to claim 1.

18. The modulation device according to claim 17, wherein the modulation device comprises a plurality of the modulation panels arranged in stacked and spaced apart from each other.

19. (canceled)

20. A driving method, applied to the modulation device according to claim 17, wherein the driving method comprises:
providing the driving signal to the driving structure, so that the driving structure drives the polar plate to move in response to the driving signal, to change the size of the overlap region of the orthographic projection of the polar plate on the base plate and the slit, to adjust the resonant frequency of the resonant structure.

21-23. (canceled)

24. A preparation method of a modulation unit, comprising:
providing a base plate, wherein the base plate comprises a substrate and a metal layer provided on one side of the substrate, and the metal layer is provided with a slit;
forming a driving layer on one side of the base plate to obtain the modulation unit; wherein the driving layer comprises a polar plate and a driving structure, with a gap between the polar plate and the base plate, and the modulation unit comprises at least one resonant structure, and the resonant structure comprises the slit, the polar plate and the driving structure, within the same resonant structure, the driving structure is connected to the polar plate for driving the polar plate to move in response to a driving signal, to change a size of an overlap region of an orthographic projection of the polar plate on the base plate and the slit, to adjust a resonant frequency of the resonant structure.

25. (canceled)
